(19) United States
(12) Patent Application Publication
(10) Pub. No.: US 2018/0131392 A1
(43) Pub. Date: May 10, 2018

(54) NR LDPC With Interleaver

(71) Applicant: MediaTek Inc., Hsinchu City (TW)

(72) Inventors: Timothy Perrin Fisher-Jeffes, Cambridge, MA (US); Wei-Jen Chen, Hsinchu City (TW); Ju-Ya Chen, Kaohsiung City (TW); Mao-Ching Chiu, Hsinchu City (TW); Yen-Shuo Chang, Hsinchu City (TW); Cheng-Yi Hsu, Hsinchu City (TW)

(21) Appl. No.: 15/802,265

(22) Filed: Nov. 2, 2017

Related U.S. Application Data
(60) Provisional application No. 62/417,391, filed on Nov. 4, 2016.

(51) Int. Cl. H03M 13/25; H03M 13/27; H04L 1/00

(52) U.S. Cl. CPC H03M 13/255; H04L 1/0071; H03M 13/27

(57) ABSTRACT

Concepts and schemes pertaining to information coding for mobile communications are described. A processor of an apparatus encodes data to provide encoded data. The processor also transmits the encoded data to a network node of a wireless network. In encoding the data, the processor encodes the data with a low-density parity-check (LDPC) code to provide LDPC-coded data. Moreover, the processor processes the LDPC-coded data with a forward error correction (FEC) robustness enhancement function to provide the encoded data. The FEC robustness enhancement function includes an interleaving function that interleaves the LDPC-coded data to provide the encoded data, an interlacing function that interlaces the LDPC-coded data to provide the encoded data, or a bit-reordering function that reorders bits of the LDPC-coded data to provide the encoded data.

### CROSS REFERENCE TO RELATED PATENT APPLICATIONS

The present disclosure claims the priority benefit of U.S. Provisional Patent Application Ser. No. 62/417,391, filed 4 Nov. 2016, the content of which is herein incorporated by reference in its entirety.

### TECHNICAL FIELD

The present disclosure is generally related to information coding and, more particularly, to low-density parity-check (LDPC) with interleaver for mobile communications.

### BACKGROUND

Unless otherwise indicated herein, approaches described in this section are not prior art to the claims listed below and are not admitted as prior art by inclusion in this section.

In 5th-generation (5G) New Radio (NR) mobile communications, LDPC is used in NR data channel. Moreover, in NR, it is desirable to have LDPC support hybrid automatic repeat request (HARQ) with incremental redundancy (HARQ-IR) for forward error-correction coding and error control. For one thing, burst interference from high-priority channels, such as ultra-reliable low-latency communication (URLLC), tend to be harmful for NR LDPC. For instance, URLLC may cause interference on other categories of 5G NR services such as, for example, enhanced mobile broadband (eMBB). Moreover, performance loss on NR LDPC can be observed when burst interference hits on systematic bits or parity bits without interleaver.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to propose various novel concepts and schemes pertaining to NR LDPC with interleaver, which can be implemented in next-generation communications, whether wired or wireless, including 5G NR wireless communications. More specifically, utilization of an interleaver with NR LDPC is proposed herein to boost performance for NR LDPC. The interleaver may be pseudo-random. Alternatively, the interleaver may be substituted by an interlacing function or a bit-reordering function.

In one aspect, a method may involve a processor of an apparatus encoding data to provide encoded data. Specifically, the method may involve the processor encoding the data with a LDPC code to provide LDPC-coded data, and processing the LDPC-coded data with a forward error correction (FEC) robustness enhancement function to provide the encoded data. The method may further involve the processor transmitting the encoded data to a network node of a wireless network.

In one aspect, a method may involve a processor of an apparatus receiving encoded data from a network node of a wireless network. The method may also involve the processor decoding the encoded data to provide decoded data. Specifically, the method may involve the processor processing the encoded data with a FEC robustness enhancement function to provide processed data, and decoding the processed data with a LDPC code to provide the decoded data.

In one aspect, an apparatus may include a transceiver and a processor coupled to the transceiver. The transceiver may be capable of wireless communications with at least one network node of a wireless network. The processor may include an encoder capable of encoding first data to provide encoded data. The encoder may encode the first data with a LDPC code to provide LDPC-coded data. The encoder may also process the LDPC-coded data with a first FEC robustness enhancement function to provide the encoded data. The processor may also include a decoder capable of decoding second data to provide decoded data. The decoder may process the second data with a second FEC robustness enhancement function to provide processed data. The decoder may also decode the processed data with the LDPC code to provide the decoded data.

It is noteworthy that, although description of the proposed scheme and various examples is provided below in the context of 5G NR wireless communications, the proposed concepts, schemes and any variation(s)/derivative(s) thereof may be implemented in communications in accordance with other protocols, standards and specifications where implementation is suitable. Thus, the scope of the proposed scheme is not limited to the description provided herein.

### BRIEF DESCRIPTION OF THE DRAWINGS

The accompanying drawings are included to provide a further understanding of the disclosure, and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation in order to clearly illustrate the concept of the present disclosure.

FIG. 1 illustrates an example encoder architecture and an example decoder architecture in accordance with an implementation of the present disclosure.

FIG. 2 is a diagram of an example base matrix for LDPC code in accordance with an implementation of the present disclosure.

FIG. 3 is a block diagram of an example apparatus in accordance with an implementation of the present disclosure.

FIG. 4 is a flowchart of an example process in accordance with an implementation of the present disclosure.

FIG. 5 is a flowchart of an example process in accordance with an implementation of the present disclosure.

### DETAILED DESCRIPTION OF PREFERRED IMPLEMENTATIONS

Detailed embodiments and implementations of the claimed subject matters are disclosed herein. However, it shall be understood that the disclosed embodiments and implementations are merely illustrative of the claimed subject matters which may be embodied in various forms. The present disclosure may, however, be embodied in many different forms and should not be construed as limited to the exemplary embodiments and implementations set forth herein. Rather, these exemplary embodiments and implementations are provided so that description of the present disclosure is thorough and complete and will fully convey the scope of the present disclosure to those skilled in the art. In the description below, details of well-known features and techniques may be omitted to avoid unnecessarily obscuring the presented embodiments and implementations.

### Overview

Under the proposed concepts and schemes in accordance with the present disclosure, NR LDPC code block may include an interleaving function, an interlacing function, or a bit-reordering function to achieve improved performance. That is, a LDPC code with an interleaving function, an interlacing function, or a bit-reordering function may mitigate effects of burst interference as well as noise from high-priority channels.

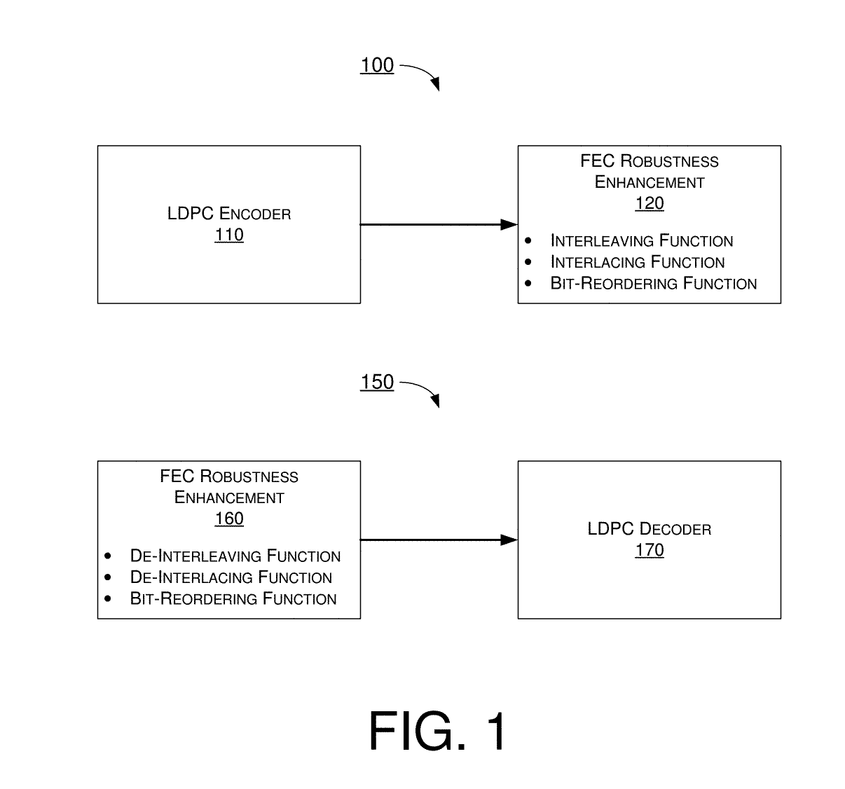

FIG. 1 illustrates an example encoder architecture 100 and an example decoder architecture 150 in accordance with an implementation of the present disclosure. Referring to FIG. 1, encoder architecture 100 may include an LDPC encoder block 110 and a first forward error correction (FEC) robustness enhancement block 120. LDPC encoder block 110 may be configured, designed or otherwise adapted to perform LDPC encoding. First FEC robustness enhancement block 120 may be configured, designed or otherwise adapted to provide an interleaving function, an interlacing function, or a bit-reordering function. Each of encoder block 110 and first FEC robustness enhancement block 120 may be implemented by hardware, software or a combination of hardware and software.

Additionally, referring to FIG. 1, decoder architecture 150 may include a second FEC robustness enhancement block 160 and an LDPC decoder block 170. Second FEC robustness enhancement block 160 may be configured, designed or otherwise adapted to provide a de-interleaving function, a de-interlacing function, or a bit-reordering function. LDPC decoder block 170 may be configured, designed or otherwise adapted to perform LDPC decoding. Each of second FEC robustness enhancement block 160 and LDPC decoder block 170 may be implemented by hardware, software or a combination of hardware and software.

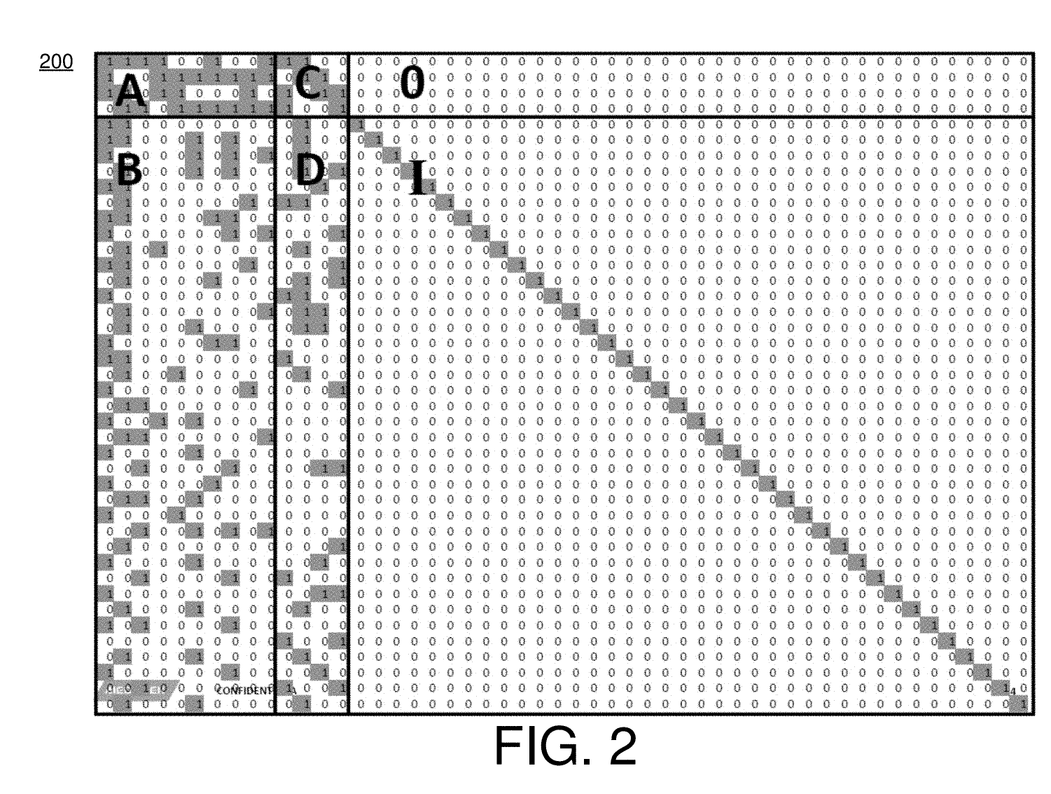

Under the proposed concepts and schemes, NR LDPC may support HARQ-IR. In particular, a raptor-like structure may be utilized to extend the parity bits for HARQ-IR. FIG. 2 illustrates an example base matrix 200 for LDPC code in accordance with an implementation of the present disclosure. For base matrix 200 of dimensions M×N with K information bits and N=K+M, the base matrix may be mathematically expressed as follows:

$$\begin{matrix}{H}_{M \times N} = [ \begin{matrix}{A}_{L \times K} & {C}_{L \times L} & {0}_{L \times ( M - L )} \\ {B}_{( M - L ) \times K} & {D}_{( M - L ) \times K} & {I}_{( M - L ) \times ( M - L )}\end{matrix} ] \\ = [ \begin{matrix}{s}_{1} & … & {s}_{K} & {p}_{1} & … & {p}_{M}\end{matrix} ]\end{matrix}$$

Here, sᵢ denotes column vector related to systematic bit with dimension M×1, and pᵢ denotes column vector related to parity bit with dimension M×1. As an example, the utilization of a bit-reordering function with the base matrix may be mathematically expressed as follows:

H_{M×N}·Π_{reorder}

Accordingly, by using an interleaver with NR LDPC, which may be a pseudo-random interleaver, data loss may be spread out through fading. Moreover, correlations in related data streams may be broken up. Moreover, it may also be overblown for this particular usage as LDPC codes inherently do not have bit-ordering properties that would result in correlated data.

Under the proposed concepts and schemes, a full interleaver of systematic bits and parity bits may be mathematically as follows:

$$[ \begin{matrix}{s}_{11} & … & {s}_{1 K} & {p}_{11} & … & {p}_{1 M} \\ {s}_{21} & … & {s}_{2 K} & {p}_{21} & & {p}_{2 M} \\ ⋮ & & ⋮ & ⋮ & & ⋮ \\ {s}_{M 1} & … & {s}_{MK} & {p}_{M 1} & … & {p}_{M M}\end{matrix} ] \cdot {Π}_{full - interleaver} = [ \begin{matrix}{s}_{11} & {p}_{11} & {s}_{12} & {p}_{12} & {s}_{13} & … \\ {s}_{21} & {s}_{22} & {p}_{21} & {s}_{23} & {p}_{22} & … \\ ⋮ & & ⋮ & ⋮ & & ⋮ \\ {s}_{M 1} & {p}_{M 1} & {P}_{M 2} & {s}_{M 2} & {p}_{M 3} & …\end{matrix} ]$$

Under the proposed concepts and schemes, interleaving of systematic bits and parity bits according to an interlacing function may be mathematically as follows:

[s₁ . . . s_{K} p₁ . . . p_{M}]·Π_{interlacing}=[s₁ p₁ s₂ p₂ . . . p_{M}]

Under the proposed concepts and schemes, reordering of systematic bits and parity bits according to a bit-reordering function may be mathematically as follows:

[s₁ . . . s_{K} p₁ . . . p_{M}]·Π_{re-ordering}=[s₁ s₂ p₁ p₂ p₃ s₃ s₄ p₄ p₅ p₆ . . . s_{E-3} s_{E} p_{M-2} p_{M-2} p_{M}]

The bit-reordering function may be code rate-dependent. Alternatively, the bit-reordering function may be code rate-independent. Moreover, the interleaver may be pseudo-random.

### Illustrative Implementations

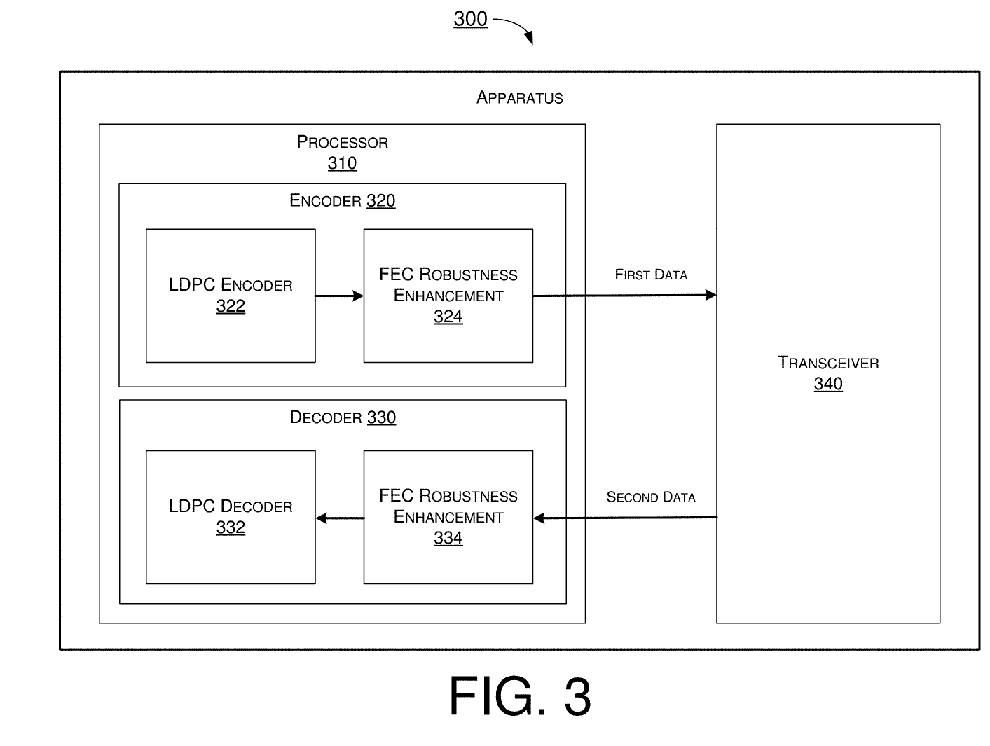

FIG. 3 illustrates an example apparatus 300 in accordance with an implementation of the present disclosure. Apparatus 300 may perform various functions as a communication device to implement concepts, schemes, techniques, processes and methods described herein pertaining to NR LDPC with interleaver, including those described above with respect to FIG. 1 and FIG. 2 as well as processes 400 and 500 described below. More specifically, apparatus 300 may implement various aspects of the proposed concepts and schemes pertaining to NR LDPC code block with an interleaving function, an interlacing function, or a bit-reordering function to achieve improved performance by mitigating effects of burst interference as well as noise from high-priority channels.

Apparatus 300 may be a part of an electronic apparatus which may be a communication device, a computing apparatus, a portable or mobile apparatus, or a wearable apparatus. For instance, apparatus 300 may be implemented in a user equipment, a base station, a smartphone, a smartwatch, a smart bracelet, a smart necklace, a personal digital assistant, or a computing device such as a tablet computer, a laptop computer, a notebook computer, a desktop computer, or a server. Alternatively, apparatus 300 may be implemented in the form of one or more integrated-circuit (IC) chips such as, for example and not limited to, one or more single-core processors, one or more multi-core processors, or one or more complex-instruction-set-computing (CISC) processors.

Apparatus 300 may include at least some of those components shown in FIG. 3. For instance, apparatus 300 may include at least a processor 310. Additionally, apparatus 300 may include a transceiver 340 configured to engage in wireless communications by transmitting and receiving data wirelessly (e.g., in compliance with one or more 3GPP and 5G NR stands, protocols, specifications and/or any applicable wireless protocols and standards). Apparatus 300 may further include other components (e.g., memory, power system, display device and user interface device), which are not pertinent to the proposed scheme of the present disclosure and, thus, are neither shown in FIG. 3 nor described herein in the interest of simplicity and brevity.

In one aspect, processor 310 may be implemented in the form of one or more single-core processors, one or more multi-core processors, or one or more CISC processors. That is, even though a singular term “a processor” is used herein to refer to processor 310, processor 310 may include multiple processors in some implementations and a single processor in other implementations in accordance with the present disclosure. In another aspect, processor 310 may be implemented in the form of hardware (and, optionally, firmware) with electronic components including, for example and without limitation, one or more transistors, one or more diodes, one or more capacitors, one or more resistors, one or more inductors, one or more memristors and/or one or more varactors that are configured and arranged to achieve specific purposes in accordance with the present disclosure. In other words, in at least some implementations, processor 310 is a special-purpose machine specifically designed, arranged and configured to perform specific tasks including NR LDPC with interleaver in accordance with various implementations of the present disclosure.

Processor 310, as a special-purpose machine, may include non-generic and specially-designed hardware circuits that are designed, arranged and configured to perform specific tasks pertaining to NR LDPC with interleaver in accordance with various implementations of the present disclosure. In one aspect, processor 310 may execute the one or more sets of codes, programs and/or instructions (e.g., stored in memory accessible by processor 310) to perform various operations to render NR LDPC with interleaver in accordance with various implementations of the present disclosure. In another aspect, processor 310 may include an encoder 320 and a decoder 330 that, together, perform specific tasks and functions to render NR LDPC with interleaver in accordance with various implementations of the present disclosure. In some implementations, encoder architecture 100 and its functionality and capabilities described above may be implemented in or by encoder 320. In some implementations, decoder architecture 150 and its functionality and capabilities described above may be implemented in or by decoder 330. Each of encoder 320 and decoder 330 may be implemented in the form of hardware with electronic circuitry. Alternatively, each of encoder 320 and decoder 330 may be implemented in the form of software. Still alternatively, each of encoder 320 and decoder 330 may be implemented in the form of a combination of hardware and software.

In some implementations, encoder 320 may include a LDPC encoder 322 and a FEC robustness enhancement block 324, and encoder 320 may be capable of encoding first data to provide encoded data. For instance, LDPC encoder 322 may encode the first data with a LDPC code to provide LDPC-coded data. Moreover, FEC robustness enhancement block 324 may process the LDPC-coded data with a first FEC robustness enhancement function to provide the encoded data. In some implementations, the first FEC robustness enhancement function may include one of the following functions: an interleaving function that interleaves the LDPC-coded data to provide the encoded data, an interlacing function that interlaces the LDPC-coded data to provide the encoded data, or a bit-reordering function that reorders bits of the LDPC-coded data to provide the encoded data.

In some implementations, decoder 330 may include a LDPC decoder 332 and a FEC robustness enhancement block 334, and decoder 330 may be capable of decoding second data to provide decoded data. For instance, FEC robustness enhancement block 334 may process the second data with a second FEC robustness enhancement function to provide processed data. Moreover, LDPC decoder 332 may decode the processed data with the LDPC code to provide the decoded data. In some implementations, the second FEC robustness enhancement function may include one of the following: a de-interleaving function that de-interleaves the second data to provide the processed data, a de-interlacing function that de-interlaces the second data to provide the processed data, or a bit-reordering function that reorders bits of the second data to provide the processed data.

### Illustrative Processes

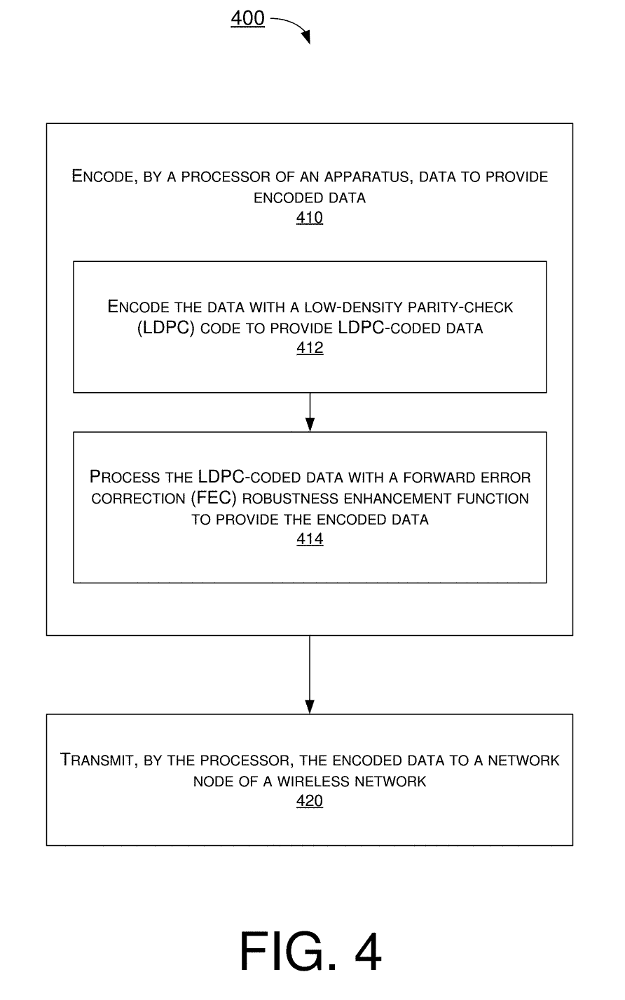

FIG. 4 illustrates an example process 400 in accordance with an implementation of the present disclosure. Process 400 may represent an aspect of implementing the proposed concepts and schemes such as those described with respect to FIG. 1˜FIG. 3. More specifically, process 400 may represent an aspect of the proposed concepts and schemes pertaining to NR LDPC with interleaver. Process 400 may include one or more operations, actions, or functions as illustrated by one or more of blocks 410 and 420 as well as sub-blocks 412 and 414. Although illustrated as discrete blocks, various blocks of process 400 may be divided into additional blocks, combined into fewer blocks, or eliminated, depending on the desired implementation. Moreover, the blocks/sub-blocks of process 400 may be executed in the order shown in FIG. 4 or, alternatively in a different order. Process 400 may be implemented by apparatus 300 and any variations thereof. For instance, process 400 may be implemented in or by apparatus 300. Solely for illustrative purposes and without limiting the scope, process 400 is described below in the context of apparatus 300. Process 400 may begin at block 410.

At 410, process 400 may involve encoder 320 of processor 310 of apparatus 300 encoding data to provide encoded data. Process 400 may proceed from 410 to 420.

At 420, process 400 may involve processor 310 transmitting, via transceiver 340, the encoded data to a network node of a wireless network, which may be a 5G NR network.

With respect to encoding the data, process 400 may involve processor 310 performing a number of operations as represented by sub-blocks 412 and 414.

At 412, process 400 may involve encoder 320 of processor 310 encoding the data with a LDPC code to provide LDPC-coded data. Process 400 may proceed from 412 to 414.

At 414, process 400 may involve encoder 320 of processor 310 processing the LDPC-coded data with a FEC robustness enhancement function to provide the encoded data.

In some implementations, the FEC robustness enhancement function may include an interleaving function that interleaves the LDPC-coded data to provide the encoded data. In some implementations, the interleaving function may interleave the LDPC-coded data with a pseudo-random interleaver.

In some implementations, the FEC robustness enhancement function may include an interlacing function that interlaces the LDPC-coded data to provide the encoded data.

In some implementations, the FEC robustness enhancement function may include a bit-reordering function that reorders bits of the LDPC-coded data to provide the encoded data. In some implementations, the bit-reordering function may be code rate-dependent. Alternatively, the bit-reordering function may be code rate-independent.

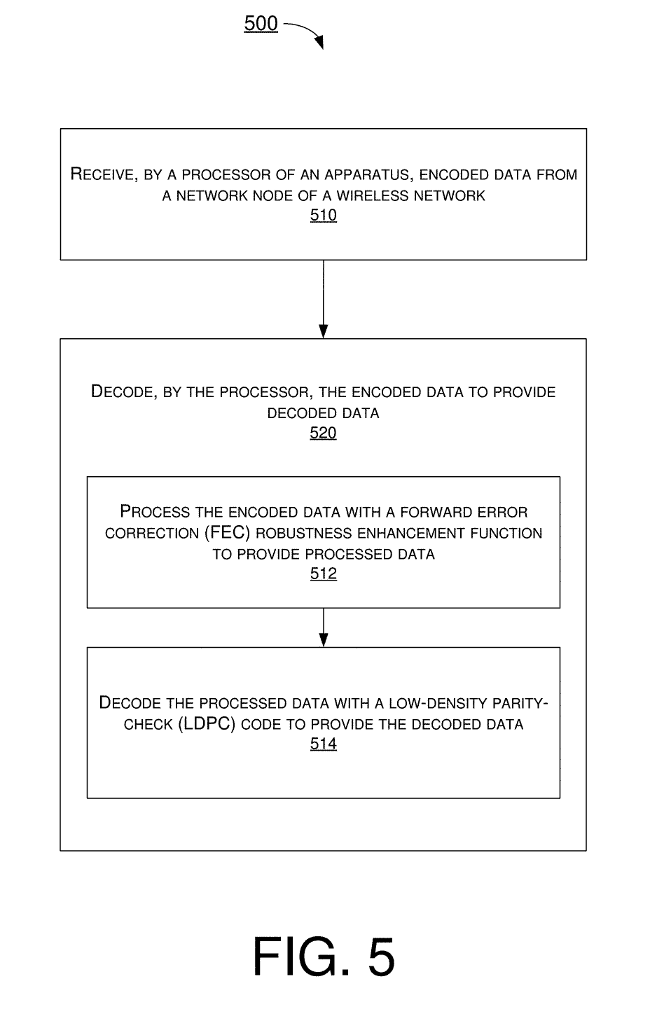

FIG. 5 illustrates an example process 500 in accordance with an implementation of the present disclosure. Process 500 may represent an aspect of implementing the proposed concepts and schemes such as those described with respect to FIG. 1˜FIG. 3. More specifically, process 500 may represent an aspect of the proposed concepts and schemes pertaining to NR LDPC with interleaver. Process 500 may include one or more operations, actions, or functions as illustrated by one or more of blocks 510 and 520 as well as sub-blocks 512 and 514. Although illustrated as discrete blocks, various blocks of process 500 may be divided into additional blocks, combined into fewer blocks, or eliminated, depending on the desired implementation. Moreover, the blocks/sub-blocks of process 500 may be executed in the order shown in FIG. 5 or, alternatively in a different order. Process 500 may be implemented by apparatus 300 and any variations thereof. For instance, process 500 may be implemented in or by apparatus 300. Solely for illustrative purposes and without limiting the scope, process 500 is described below in the context of apparatus 300. Process 500 may begin at block 510.

At 510, process 500 may involve processor 310 of apparatus 300 receiving, via transceiver 340, encoded data from a network node of a wireless network, which may be a 5G NR network. Process 500 may proceed from 510 to 520.

At 520, process 500 may involve decoder 330 of processor 310 decoding the encoded data to provide decoded data.

With respect to decoding the encoded data, process 500 may involve processor 310 performing a number of operations as represented by sub-blocks 512 and 514.

At 512, process 500 may involve decoder 330 of processor 310 processing the encoded data with a FEC robustness enhancement function to provide processed data. Process 500 may proceed from 512 to 514.

At 514, process 500 may involve decoder 330 of processor 310 decoding the processed data with a LDPC code to provide the decoded data.

In some implementations, the FEC robustness enhancement function may include a de-interleaving function that de-interleaves the encoded data to provide the processed data. In some implementations, the de-interleaving function may de-interleave the encoded data with a pseudo-random de-interleaver.

In some implementations, the FEC robustness enhancement function may include a de-interlacing function that de-interlaces the encoded data to provide the processed data.

In some implementations, the FEC robustness enhancement function may include a bit-reordering function that reorders bits of the encoded data to provide the processed data. In some implementations, the bit-reordering function may be code rate-dependent. Alternatively, the bit-reordering function may be code rate-independent.

### Additional Notes

The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A method, comprising:
encoding, by a processor of an apparatus, data to provide encoded data, the encoding comprising:
encoding the data with a low-density parity-check (LDPC) code to provide LDPC-coded data; and
processing the LDPC-coded data with a forward error correction (FEC) robustness enhancement function to provide the encoded data; and
transmitting, by the processor, the encoded data to a network node of a wireless network.

2. The method of claim 1, wherein the FEC robustness enhancement function comprises an interleaving function that interleaves the LDPC-coded data to provide the encoded data.

3. The method of claim 2, wherein the interleaving function interleaves the LDPC-coded data with a pseudo-random interleaver.

4. The method of claim 1, wherein the FEC robustness enhancement function comprises an interlacing function that interlaces the LDPC-coded data to provide the encoded data.

5. The method of claim 1, wherein the FEC robustness enhancement function comprises a bit-reordering function that reorders bits of the LDPC-coded data to provide the encoded data.

6. The method of claim 5, wherein the bit-reordering function is code rate-dependent.

7. The method of claim 5, wherein the bit-reordering function is code rate-independent.

8. The method of claim 1, wherein the wireless network comprises a 5^{th} Generation (5G) New Radio (NR) network.

9. A method, comprising:
receiving, by a processor of an apparatus, encoded data from a network node of a wireless network; and
decoding, by the processor, the encoded data to provide decoded data, the decoding comprising:
processing the encoded data with a forward error correction (FEC) robustness enhancement function to provide processed data; and
decoding the processed data with a low-density parity-check (LDPC) code to provide the decoded data.

10. The method of claim 9, wherein the FEC robustness enhancement function comprises a de-interleaving function that de-interleaves the encoded data to provide the processed data.

11. The method of claim 10, wherein the de-interleaving function de-interleaves the encoded data with a pseudo-random de-interleaver.

12. The method of claim 9, wherein the FEC robustness enhancement function comprises a de-interlacing function that de-interlaces the encoded data to provide the processed data.

13. The method of claim 9, wherein the FEC robustness enhancement function comprises a bit-reordering function that reorders bits of the encoded data to provide the processed data.

14. The method of claim 13, wherein the bit-reordering function is code rate-dependent.

15. The method of claim 13, wherein the bit-reordering function is code rate-independent.

16. The method of claim 9, wherein the wireless network comprises a 5^{th} Generation (5G) New Radio (NR) network.

17. An apparatus, comprising:
a transceiver capable of wireless communications with at least one network node of a wireless network; and
a processor coupled to the transceiver, the processor comprising:
an encoder capable of encoding first data to provide encoded data by performing operations comprising:
encoding the first data with a low-density parity-check (LDPC) code to provide LDPC-coded data; and
processing the LDPC-coded data with a first forward error correction (FEC) robustness enhancement function to provide the encoded data.

18. The apparatus of claim 17, wherein the first FEC robustness enhancement function comprises one of:
an interleaving function that interleaves the LDPC-coded data to provide the encoded data;
an interlacing function that interlaces the LDPC-coded data to provide the encoded data; or
a bit-reordering function that reorders bits of the LDPC-coded data to provide the encoded data.

19. The apparatus of claim 17, wherein the processor further comprises:
a decoder capable of decoding second data to provide decoded data by performing operations comprising:
processing the second data with a second FEC robustness enhancement function to provide processed data; and
decoding the processed data with the LDPC code to provide the decoded data.

20. The apparatus of claim 19, wherein the second FEC robustness enhancement function comprises one of:
a de-interleaving function that de-interleaves the second data to provide the processed data;
a de-interlacing function that de-interlaces the second data to provide the processed data; or
a bit-reordering function that reorders bits of the second data to provide the processed data.
